(19) United States
(12) Patent Application Publication
(10) Pub. No.: US 2006/0164144 A1
(43) Pub. Date: Jul. 27, 2006

(54) Flip-flop circuit and semiconductor device

(75) Inventor: Masaaki Souda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/336,957

(22) Filed: Jan. 23, 2006

(30) Foreign Application Priority Data
Jan. 24, 2005 (JP) 2005-015480

(51) Int. Cl. H03K 3/037

(52) U.S. Cl. 327/218

(57) ABSTRACT

A flip-flop circuit capable of stable, high-speed operation even at low voltages includes a clock buffer for outputting differential clock signals with an offset to first and second latch circuits, the clock signals having a threshold-value voltage of a transistor as the offset voltage. The first and second latch circuits are so adapted that input signals are output upon switching between a data-through operation and a data latching operation with respect to the input signals by operating the MOS transistor, which has the threshold-value voltage, by the clock signals having the offset. The first latch circuit receives input differential signals as inputs, performs a data-through operation and a data holding operation by the differential clock signals with the offset and supplies the output differential signals to the second latch circuit. The second latch circuit performs a data holding operation and data-through operation by differential clock signals with an offset, these signals being opposite in phase to the differential clock signals with the offset supplied to the first latch circuit, and outputs the resultant signals as output differential signals.

### FIELD OF THE INVENTION

This invention relates to a flip-flop circuit and to a semiconductor device. More particularly, the invention relates to a CML (Current Mode Logic)-type flip-flop circuit and to a semiconductor device on which the flip-flop circuit is mounted.

### BACKGROUND OF THE INVENTION

CML-type flip-flop circuits capable of high-speed operation are used in LSI chips for high-speed communication. CML-type flip-flop circuits that operate at lower voltages as a result of more minute processes developed in recent years are known. A data latch circuit disclosed in Patent Document 1 is an example of such a flip-flop circuit that operates a low voltages. The circuit disclosed in Patent Document 1 is an ECL (Emitter Coupled Logic) data latch constituted by a bipolar circuit of the kind illustrated in FIG. 13.

As shown in FIG. 13, the data latch circuit includes a transistor 105 connected to the emitters of a data-input differential circuit (transistors 101, 102) that receives data input from input terminals D+ and D−, and a transistor 106 connected to the emitters of a toggle differential circuit (transistors 103, 104) that performs a toggling operation. The collectors of transistors 101 and 103 are tied together and connected to an additional resistor 107 and to an output terminal Q−, and the collectors of transistors 102 and 104 are tied together and connected to an additional resistor 108 and to an output terminal Q+.

A clock signal Clk is supplied to a transistor 109, which constitutes an emitter follower, and to a transistor 113, which constructs a current mirror with the transistor 105, via a resistor 111 connected to the source of the transistor 109. A signal that is the inverse of the clock signal Clk is supplied to a transistor 110, which constitutes an emitter follower, and to a transistor 114, which constructs a current mirror with the transistor 106, via a resistor 112 connected to the emitter of the transistor 110.

If the clock signal Clk is at the high level, the transistor 105 turns on and the data-input differential circuit (transistors 101, 102) operates. At this time the signal that is the inverse of the clock signal Clk is at the low level, transistor 106 turns off and so do the toggle differential circuit (transistors 103, 104). As a result, the data input from the input terminals D+, D− is amplified by the data-input differential circuit (transistors 101, 102) and is output from the output terminals Q+, Q− by being passed through.

On the other hand, if the inverse of the clock signal Clk is at the high level, the transistor 106 turns on and the toggle differential circuit (transistors 103, 104) operates. At this time the clock signal Clk is at the low level, the transistor 105 turns off and so does the data-input differential circuit (transistors 101, 102). As a result, the toggle differential circuit (transistors 103, 104) performs a latching operation irrespective of the data input from the input terminals D+, D− and the latched content is output from the output terminals Q+, Q−.

Since the data latch circuit is thus constituted by two stages of stacked transistors, low-voltage operation is possible. A similarly constructed flip-flop circuit is also disclosed in Patent Document 2.

[Patent Document 1]

Japanese Patent Kokai Publication No. JP-A-7-30405 (FIG. 1)

[Patent Document 2]

Japanese Patent Kokai Publication No. JP-A-9-107275 (FIG. 1)

### SUMMARY OF THE DISCLOSURE

In the circuit shown in FIG. 13, the clock signal Clk and the signal that is the inverse of the clock signal Clk do not change over from the high (low) level to the low (high) level instantaneously but rather change over after a prescribed length of time. Accordingly, when the clock signal Clk attains a high speed, a problem arises in terms of the operating time of the transistors 105, 106. Specifically, there is the danger that the circuit will not operate stably. For example, when the levels of the clock signal Clk and signal that is the inverse thereof undergo the transition, a period over which both transistors 105 and 106 turn on or off simultaneously for an extremely short time occurs and the latch circuit can no longer hold the signal.

According to an aspect of the present invention, there is provided a flip-flop circuit comprising: a clock buffer circuit that outputs a clock signal with an offset having a threshold-value voltage of a transistor as an offset voltage; and a latch circuit so adapted that an input signal is output upon switching between a data-through operation and data latching operation with respect to the input signal by operating the transistor, which has a threshold-value voltage, by the clock signal with the offset.

The meritorious effects of the present invention are summarized as follows.

In accordance with the present invention, a latch circuit in which transistors are stacked in two stages is driven by a clock signal having an offset voltage in the vicinity of the threshold value of a transistor. As a result, stable, high-speed operation is possible even at low voltages.

Other features and advantages of the present invention will be apparent from the following description taken in conjunction with the accompanying drawings, in which like reference characters designate the same or similar parts throughout the figures thereof.

Further aspects of the present invention are shown as follows:

According to a second aspect, the clock signal with the offset comprises a set of differential clock signals with an offset, the differential signals being opposite in phase from each other; and

the latch circuit includes:

a first differential pair, in which the input signal is input as differential data, for performing a data-through operation to output the data to a pair of differential data output terminals;

a second differential pair for subjecting the differential data, which is output by the first differential pair, to a data holding operation and then outputting the data to the differential data output terminal;

a first transistor, which has a gate terminal that receives one clock signal of the differential clock signal with the offset, for driving the first differential pair when this one clock signal attains an active level; and

a second transistor, which has a gate terminal that receives the other clock signal of the differential clock signal with the offset, for driving the second differential pair when this other clock signal attains an active level;

the offset voltage being decided in such a manner that the sum of driving currents of the first and second transistors is rendered constant.

According to a third aspect, the second differential pair comprises third and fourth transistors;

the first transistor has a source terminal connected to ground and a drain terminal connected to a common-source side of the first differential pair, first and second loads and the differential data output terminals being connected to a drain side of the first differential pair;

the second terminal has a source terminal connected to ground and a drain terminal connected to a common-source side of the second differential pair; and

the third and fourth transistors have gate and drain terminals, respectively, tied together and connected to one of the differential data output terminals, and the third and fourth transistors have drain and gate terminals, respectively, tied together and connected to the other of the differential data output terminals.

According to a fourth aspect, the clock buffer circuit comprises:

a third differential pair that receives differential clock signals as an input;

a current source for driving the third differential pair;

third and fourth loads having first ends connected to respective ones of outputs of the third differential pair;

a pair of clock signal output terminals, which are connected to respective ones of the outputs of the third differential pair, for outputting the clock signal with the offset as differential clock signals; and

an offset voltage generating circuit, to which other ends of the third and fourth loads are connected in common, for generating the offset voltage.

In the fourth aspect, the offset voltage generating circuit comprises a fifth transistor having gate and drain terminals tied together and connected to the third and fourth loads, and a source terminal connected to ground.

In the fourth aspect, the offset voltage generating circuit comprises:

a sixth transistor having gate and drain terminals tied together and connected to a current source, and a source terminal connected to ground; and

a voltage follower receiving drain potential of the sixth transistor as an input and having an output connected to the third and fourth loads.

In the fourth aspect, the third and fourth loads of the clock buffer circuit comprise seventh and eighth transistors, and the clock buffer circuit comprises:

ninth and tenth transistors equivalent to the first and second transistors, respectively, in the flip-flop circuit of the third aspect;

loads, which are connected to drains of the ninth and tenth transistors, respectively, equivalent to the first and second loads in the flip-flop circuit of the third aspect;

a second amplifier, which has a first input terminal to which the drains of the ninth and tenth transistors are connected in common and a second input terminal to which a first reference voltage is supplied, for amplifying a difference voltage across these first and second input terminals; and

a second capacitor, which is connected to an output of the second amplifier, for converting output current of the second amplifier to voltage;

the ninth and tenth transistors having gates to which respective ones of the pair of clock signal input terminals are connected;

the output of the second amplifier being connected to gate terminals of the seventh and eighth transistors.

According to a fifth aspect, the flip-flop circuit further comprises a control circuit that generates a second reference voltage in order to perform control so as to render constant an output of the latch circuit, to output a control signal to the latch circuit based upon the second reference voltage;

wherein the latch circuit is controlled based upon the control signal.

In the fifth aspect, the latch circuit is a circuit in which the first and second loads in the flip-flop circuit of the third aspect comprise 11th and 12th transistors, respectively, and the control signal is supplied to both gate terminals so as to control resistance values of the 11th and 12th transistors; and

the control circuit further comprises:

a circuit in which all gate terminals of the first and second differential pairs in the latch circuit are connected to a power supply and all drain terminals are tied together to construct the latch circuit;

a third amplifier, which has a first input terminal to which all drain terminals are connected and a second input terminal to which the second reference voltage is supplied, for amplifying a difference voltage across these first and second terminals; and

a third capacitor, which is connected to an output of the third amplifier, for converting output current of the third amplifier to voltage;

the output of the third amplifier being connected to gate terminals of load transistors of the first and second differential pairs and being adopted as the control signal.

According to a sixth aspect, there is provided a semiconductor device in which flip-flop circuits of the first aspect is provided on the same chip.

### BRIEF DESCRIPTION OF THE DRAWINGS

FIG. 1 is a circuit diagram illustrating a flip-flop circuit according to a first embodiment of the present invention;

FIG. 2 is a diagram illustrating a clock signal waveform of an offset-adjusting clock buffer according to the first embodiment;

FIG. 3 is a diagram illustrating the operating waveforms of a flip-flop circuit according to the first embodiment;

FIG. 4 is a circuit diagram illustrating a latch circuit according to the first embodiment;

FIG. 5 is a circuit diagram of an offset-adjusting clock buffer according to the first embodiment;

FIGS. 6A, 6B and 6C are diagrams illustrating the relationship between a clock signal and offset voltage;

FIG. 7 is a circuit diagram of an offset generating circuit according to the first embodiment;

FIG. 8 is a circuit diagram of another offset generating circuit according to the first embodiment;

FIG. 9 is a circuit diagram of another offset-adjusting clock buffer according to the first embodiment;

FIG. 10 is a circuit diagram illustrating a flip-flop circuit according to a second embodiment of the present invention;

FIG. 11 is a circuit diagram illustrating a latch circuit according to the second embodiment;

FIG. 12 is a circuit diagram of a control circuit according to the second embodiment; and

FIG. 13 is a circuit diagram of a CML-type flip-flop circuit according to an example of the prior art.

### PREFERRED EMBODIMENTS OF THE INVENTION

Preferred embodiments of the present invention will now be described with reference to the drawings.

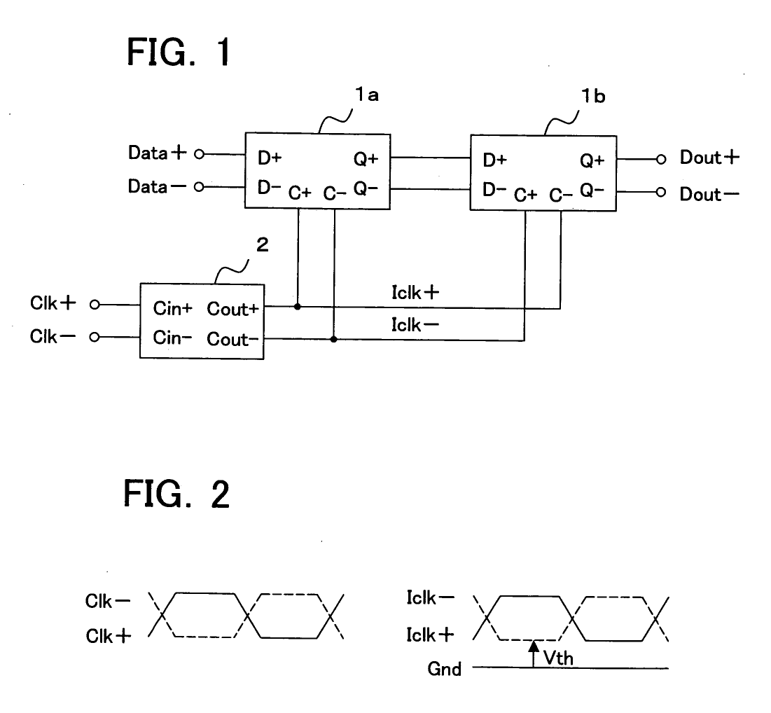

A flip-flop circuit according to a mode of practicing the present invention has an offset-adjusting clock buffer circuit (2 in FIG. 1) that outputs differential clock signals (Iclk+, Iclk− in FIG. 1) w ith an offset, the signals having a threshold-value voltage of a MOS transistor as an offset voltage. Further, the flip-flop circuit has two latch circuits (1a, 1b in FIG. 1) for outputting input signals upon switching between a data-through operation and data latching operation with respect to the input signals by operating the MOS transistor, which has the threshold-value voltage, by the clock signals having the offset. The first latch circuit (1a in FIG. 1) receives input signals (Data+, Data− in FIG. 1), performs a data-through operation and a data holding operation by the differential clock signals with the offset and supplies the output differential signals to the second latch circuit (1b in FIG. 1). This latch circuit (1b in FIG. 1) subjects the differential signals that are output from the first latch circuit (1a in FIG. 1) to a data holding operation and data-through operation by differential clock signals with an offset, these signals being opposite in phase to the differential clock signals with the offset supplied to the first latch circuit (1a in FIG. 1), and outputs the resultant signals as output differential signals (Dout+, Dout− in FIG. 1).

The latch circuits (1a, 1b in FIG. 1) are operated by the differential clocks with offset in which the offset is in the vicinity of the threshold value of the MOS transistor, as set forth above. This makes stable, high-speed operation possible even at low voltages. Embodiments of the present invention will now be described in detail with reference to the drawings.

### First Embodiment

FIG. 1 is a circuit diagram of a flip-flop circuit according to a first embodiment of the present invention. As shown in FIG. 1, the flip-flop circuit comprises latch circuits 1a, 1b and an offset-adjusting clock buffer 2. The latch circuits 1a, 1b, which are identically constructed, switch between a data latching operation and a data-through operation with respect to differential data signals that are input to data input terminals D+, D−, in response to differential clock signals that are input to clock input terminals C+, C−, and output the signals to output terminals Q+, Q−. The latch circuits 1a, 1b perform the data latching operation when the high level (active level) of the clock signal is impressed upon one clock input terminal C+, and perform the data-through operation when the high level (active level) of the clock signal is impressed upon the other clock input terminal C−. A clock signal Iclk+ is supplied to the clock input terminal C+ of the latch circuit 1a and to the clock input terminal C− of the latch circuit 1b. A clock signal Iclk− is supplied to the clock input terminal C− of the latch circuit 1a and to the clock input terminal C+ of the latch circuit 1b. The clock signals Iclk+, Iclk− are signals opposite each other in terms of phase and when one of the latch circuits 1a, 1b is performing the data latching operation, the other latch circuit performs the data-through operation. Hence, a flip-flop circuit is formed.

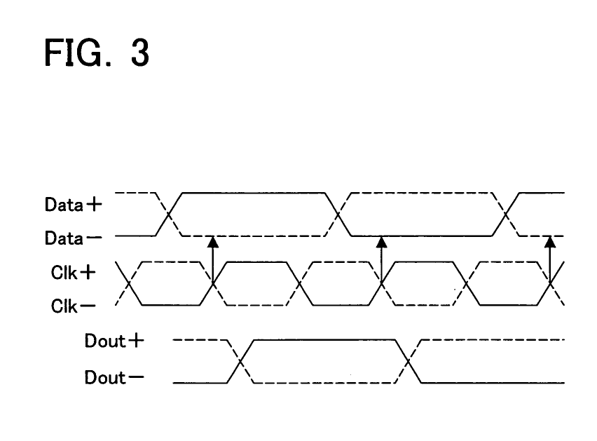

As shown in FIG. 2, the offset-adjusting clock buffer 2 outputs the clock signals Iclk+, Iclk−, which have an offset voltage in the vicinity of the threshold-value voltage Vth of a MOS transistor, from output terminals Cout+, Cout− in response to differential clock signals Clk+, Clk− that have been input to input terminals Cin+, Cin−. In this case the output signals Iclk+, Iclk− have such an offset voltage that the minimum voltage is in the vicinity of the threshold-value voltage Vth. In FIG. 1, the two latch circuits 1a, 1b and the offset-adjusting clock buffer 2 are used to input the clock signal Iclk+ to the input terminals C+, C− of the latch circuit 1a and the clock signal Iclk− to the input terminals C+, C− of the latch circuit 1b. In this case the polarities of the clock signals Iclk+, Iclk− input to the latch circuits 1a, 1b are opposite each other. Outputs Q+, Q− of the differential input data Data+, Data− that has been input to the latch circuit 1a are input to the latch circuit 1b. As shown in FIG. 3, the outputs of the latch circuit 1b are output differential signals Dout+, Dout− in which the input signals Data+, Data− have been identified in accordance with the positive-going transitions of the clock signal Clk+.

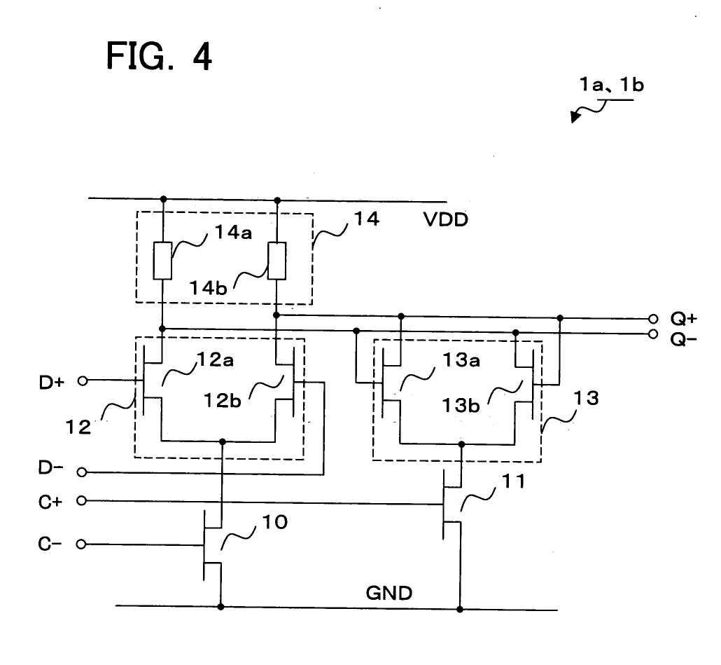

FIG. 4 is a circuit diagram illustrating an example of the structure of the latch circuits 1a, 1b. As shown in FIG. 4, each of the latch circuits 1a, 1b has NMOS transistors 10, 11, 12a, 12b, 13a, 13b and loads 14a, 14b. The NMOS transistors 12a, 12b have their sources tied together and construct a transistor differential circuit (differential pair) 12. The NMOS transistors 13a, 13b have their sources tied together and construct a transistor differential circuit (differential pair) 13. The NMOS transistors 10, 11 construct current sources for driving the transistor differential circuits 12, 13, respectively. That is, the drain of the NMOS transistor 10 is connected to the sources of the NMOS transistor 12a and NMOS transistor 12b, and the drain of the NMOS transistor 11 is connected to the sources of the NMOS transistor 13a and NMOS transistor 13b. One clock signal input terminal C− is connected to the gate of the NMOS transistor 10, and the other clock signal input terminal C+ is connected to the gate of the NMOS transistor 11.

The data input terminals D+, D− are connected to the gates of the transistor differential circuit 12, namely to the gates of the NMOS transistor 12a and NMOS transistor 12b, respectively, and the loads 14a, 14b are connected to drains of the NMOS transistor 12a and NMOS transistor 12b, respectively. The loads 14a, 14b are composed of a MOS transistor or resistance element, etc. The gates and drains of the transistor differential circuit 13 are connected to each other “crossingly” as illustrated, and the output terminals Q+, Q− are connected to respective ones of the drains. More specifically, the drain of the NMOS transistor 13a and the gate of the NMOS transistor 13b are connected to each other and to the output terminal Q+ and drain of the NMOS transistor 12b. Further, the drain of the NMOS transistor 13b and the gate of the NMOS transistor 13a are connected to each other and to the output terminal Q− and drain of the NMOS transistor 12a.

When the active level of the clock signal is supplied to the clock input terminal C+ connected to the gate of the NMOS transistor 10 in the latch circuits 1a, 1b thus constructed, the circuit performs a through operation in which the input data that has been input to the input terminals D+, D− is output to the output terminals Q+, Q− through the transistor differential circuit 12. On the other hand, when the active level of the clock signal is supplied to the clock input terminal C− connected to the gate of the NMOS transistor 11, the circuit holds the state of the output that prevailed at the input of the clock and performs a latching operation that is independent of a change in the input terminals D+, D−. Thus, the latch circuits 1a, 1b are constructed by stacked transistors the number of stages of which is only two, and the circuits operate satisfactorily even at a low power-supply voltage of 1 V.

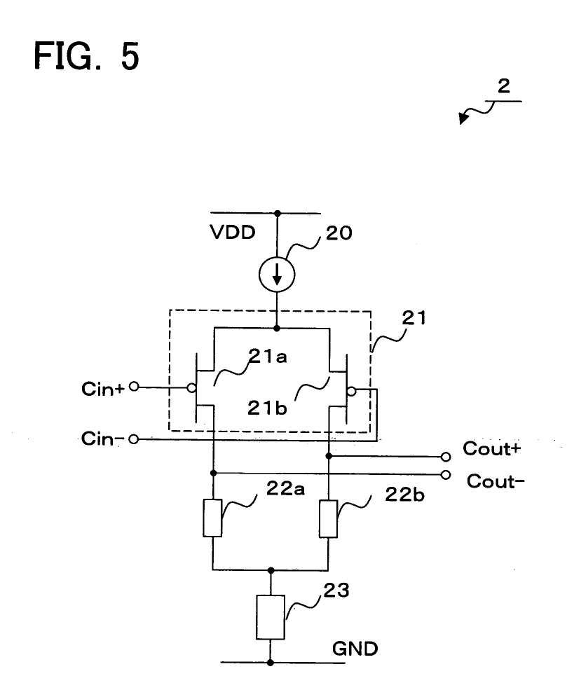

The clock signals Iclk+, Iclk− having the offset voltage in the vicinity of the threshold-value voltage Vth will be described next. FIG. 5 is a circuit diagram illustrating the structure of the offset-adjusting clock buffer 2. As shown in FIG. 5, a current source 20 constituted by a MOS transistor or the like is connected to the sources of PMOS transistors 21a, 21b that construct a transistor differential circuit 21. Clock signal input terminals Cin+, Cin− are connected to the gates of the PMOS transistors 21a, 21b, respectively. Loads 22a, 22b and clock output terminals Cout−, Cout+are connected to the drain sides of the PMOS transistors 21a, 21b, respectively. The loads 22a, 22b comprise MOS transistors or resistance elements. An offset generating circuit 23 for generating an offset voltage is connected across the loads 22a, 22b and ground GND. By generating the threshold-value voltage Vth on the side of the offset generating circuit 23 to which the loads are connected, the clock signals Iclk+, Iclk− having the offset voltage of the threshold-value voltage Vth are output from the output terminals Cout+, Cout−, respectively.

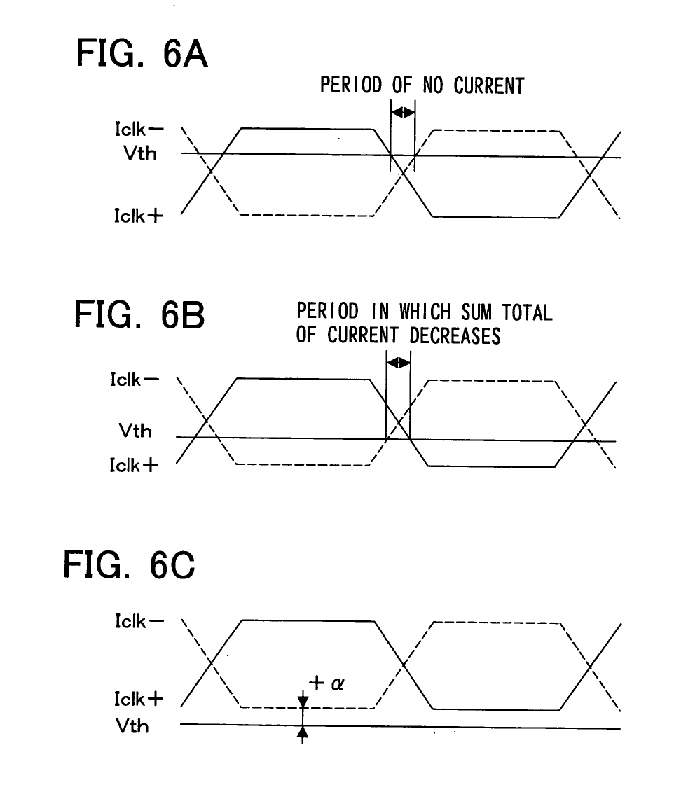

The action of the offset voltage will be described with reference to FIGS. 6A to 6C. FIG. 6A illustrates a case where the voltage of the threshold-value voltage Vth is higher than the cross points of the clock signals. In this case there is an interval of time in which the voltages of both of the clock signals Iclk+, Iclk− fall below the threshold-value voltage Vth simultaneously and hence there is a period of time in which current does not flow into either of the NMOS transistors 10, 11 shown in FIG. 4. As a result, the latch circuit no longer is capable of holding the signal and the flip-flop circuit no longer outputs the correct signal. Further, in a case where the threshold-value voltage Vth resides between the cross points of the clock signals Iclk+, Iclk− and the minimum voltage, as illustrated in FIG. 6B, there is an interval of time in which the sum total of the currents that flow into the NMOS transistors 10, 11 decreases. In this case the latch circuits 1a, 1b are capable of holding the signal but the holding power is weak owing to the decrease in current. Instances in which an error is produced in the output increase especially in case of high-speed operation.

If the minimum voltage of the clock signals Iclk+, Iclk− is set in the vicinity of the threshold-value voltage Vth, as illustrated in FIG. 6C, the sum total of the currents that flow into the NMOS transistors 10, 11 can be rendered constant and high-speed, stable operation becomes possible. With an actual MOS transistor, owing to the effects of non-linearity of the drain current versus gate voltage, an identifying operation of higher speed becomes possible by further offsetting the minimum voltage of the clock signals C+, C− from Vth by an offset amount+α.

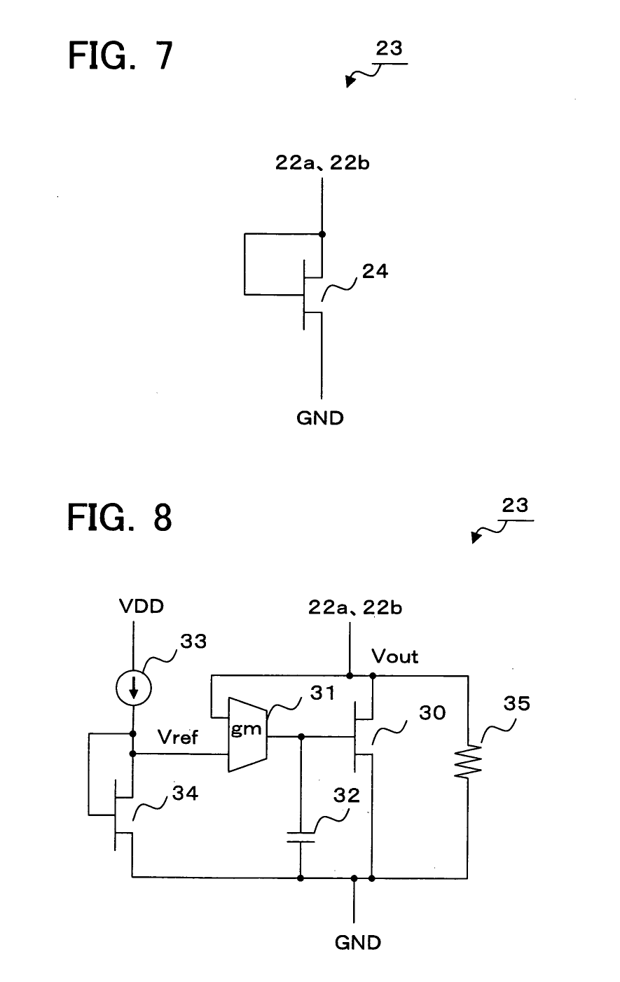

The structure of the offset generating circuit 23 will be described next. FIG. 7 is a circuit diagram illustrating an example of the offset generating circuit 23. As shown in FIG. 7, the offset generating circuit 23 comprises an NMOS transistor 24 the drain and gate of which are tied together. By making the size of the NMOS transistor 24 sufficiently large with respect to the current produced by the current source 20, the voltage across the gate and source of the NMOS transistor 24 can be made to approach the threshold-value voltage Vth. As a result, the output clock signals of the offset-adjusting clock buffer 2 have an offset voltage in the vicinity of the threshold-value voltage Vth.

FIG. 8 is a circuit diagram illustrating another example of the offset generating circuit 23. As shown in FIG. 8, the offset generating circuit 23 comprises an NMOS transistor 30, an amplifier 31, a capacitor 32, a current source 33, an NMOS transistor 34 and a resistor 35. First, a reference voltage Vref is generated in the drain of the NMOS transistor 34 by supplying current from the current source 33 to the NMOS transistor 34 the gate and drain whereof are connected together. A reference voltage near the threshold-value voltage Vth is generated by diminishing the current of the current source 33. The reference voltage Vref and output voltage Vout on the drain side of the NMOS transistor 30 are compared by the amplifier 31. If the output voltage Vout is higher than the reference voltage Vref, a current flows out from the output of the amplifier 31, the capacitor 32 is charged and the gate potential of the NMOS transistor 30 rises. As a result, the resistance across the drain and source of the NMOS transistor 30 decreases and so does the voltage of the output voltage Vout. This operation continues until the reference voltage Vref and the output voltage Vout become equal.

Conversely, if the output voltage Vout is lower than the reference voltage Vref, a current flows in from the output of the amplifier 31, the capacitor 32 is discharged, and the gate potential of the NMOS transistor 30 falls. As a result, the resistance across the drain and source of the NMOS transistor 30 rises and so does the voltage of the output voltage Vout. This operation continues until the reference voltage Vref and the output voltage Vout become equal. The offset generating circuit operates as described above so that the output clock signals of the offset-adjusting clock buffer 2 have an offset voltage in the vicinity of the threshold-value voltage Vth. It should be noted that the resistor 35 is connected in parallel across the drain and source of the NMOS transistor 30 and acts to lower the gain by lowering the resistance value of this portion of the circuit. This leads to stable operation in the form of feedback to the amplifier 31.

The offset generating circuit of FIG. 8 is more advantageous than that of FIG. 7 in that the size of the MOS transistors to the output node can be reduced and in that the output offset voltage can be controlled accurately.

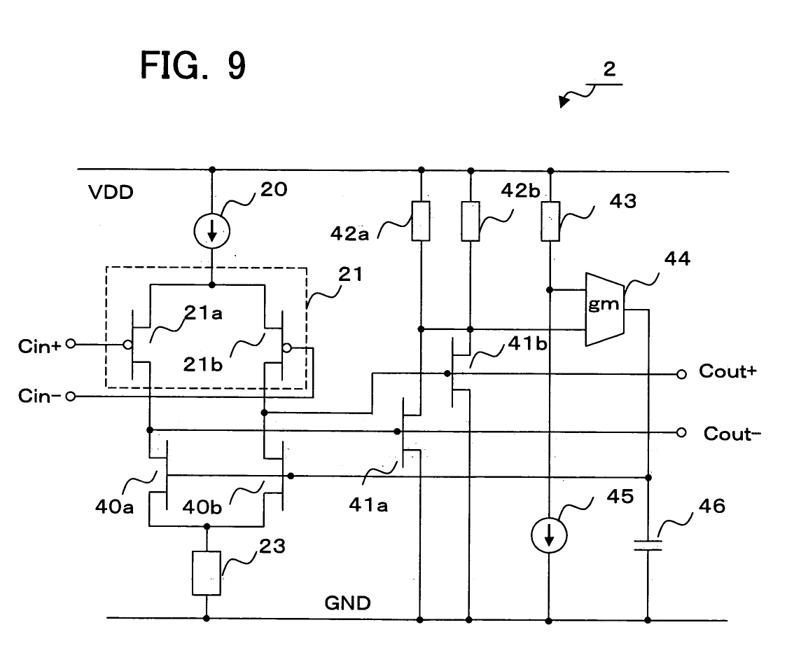

Another example of the structure of the offset-adjusting clock buffer 2 will now be described. FIG. 9 is a circuit diagram illustrating another example of the offset-adjusting clock buffer 2. With the offset-adjusting clock buffer of FIG. 5, the offset voltage of the output clocks Cout+, Cout− is adjusted. However, the offset-adjusting clock buffer shown in FIG. 9 is adapted so as to also control the amplitude of the output clocks Cout+, Cout−. By controlling amplitude, it is possible to suppress a fluctuation in the output amplitudes of the latch circuits 1a, 1b ascribable to differences in transistors and a change in the operating environment.

As shown in FIG. 9, the offset-adjusting clock buffer 2 comprises the differential pair 21 to which the clock signals Cin+, Cin− are input; the current source 20; the offset generating circuit 23; NMOS transistors 40a, 40b the load of which is the differential pair 21; NMOS transistors 41a, 41b to the gate terminals of which the output clock signals Cout+, Cout−, respectively, are connected; loads 42a, 42b that convert to voltage the current that flows into the NMOS transistors 41a, 41b; a current source 45 and load 43 for generating a reference voltage; an amplifier 44 for comparing the voltage generated by the loads 42a, 42b with the reference voltage; and a capacitor 46. It should be noted that reference characters in FIG. 9 that are identical with those in FIG. 5 represent the same components.

In the arrangement described above, the sizes of the NMOS transistors 41a, 41b and loads 42a, 42b are decided beforehand in such a manner that the current that flows into the latch circuits 1a, 1b can be detected. As a result, the average value of signal amplitude of the latch circuits 1a, 1b appears at the loads 42a, 42b. The difference between the voltage that becomes the average value and the reference voltage is amplified by the amplifier 44, the amplified signal is supplied to the gates of the NMOS transistors 40a, 40b via a capacitor that removes the high-frequency part of the output signal of amplifier 44, and the gate voltage is controlled. By virtue of such control, the amplitude of the output clocks Cout+, Cout− is controlled in such a manner that the voltage generated in the loads 42a, 42b becomes equal to the reference voltage. By using the offset-adjusting clock buffer 2 of FIG. 9, the operating amplitude of the latch circuits 1a, 1b is rendered constant irrespective of differences in MOS transistors and regardless of the operating environment, and this leads to stable operation of the flip-flop circuit.

It is preferred that flip-flop circuits constructed as set forth above be mounted on the same chip (semiconductor device). By mounting the flip-flop circuits on the same chip, differences between MOS transistors are reduced, the operating environment of the MOS transistor becomes is rendered homogeneous and the flip-flop circuits operate more stably.

In accordance with the arrangement set forth above, by applying the invention to a 0.1-μm process, it is possible to realize a semiconductor device on which is mounted a flip-flop circuit capable of operating up to about 6 Gb/s at 1V operation.

### Second Embodiment

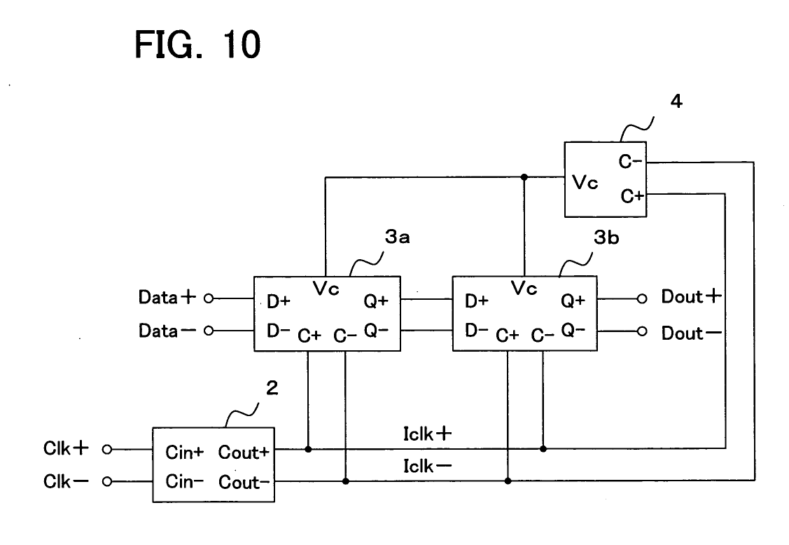

FIG. 10 is a circuit diagram of a flip-flop circuit according to a second embodiment of the present invention. As shown in FIG. 10, the flip-flop circuit has the offset-adjusting clock buffer 2, latch circuits 3a, 3b and a control circuit 4. The offset-adjusting clock buffer 2, which is implemented by the circuit shown in FIG. 5 or FIG. 9, supplies the latch circuits 3a, 3b and control circuit 4 with clock signals Iclk+, Iclk− that impart an offset voltage. The latch circuits 3a, 3b, which are identical, are latch circuits each having a control terminal Vc that is capable of controlling the internal load resistance value. The control circuit 4 generates control voltage from the clock signals Iclk+, Iclk− and supplies the voltage to the latch circuits 3a, 3b.

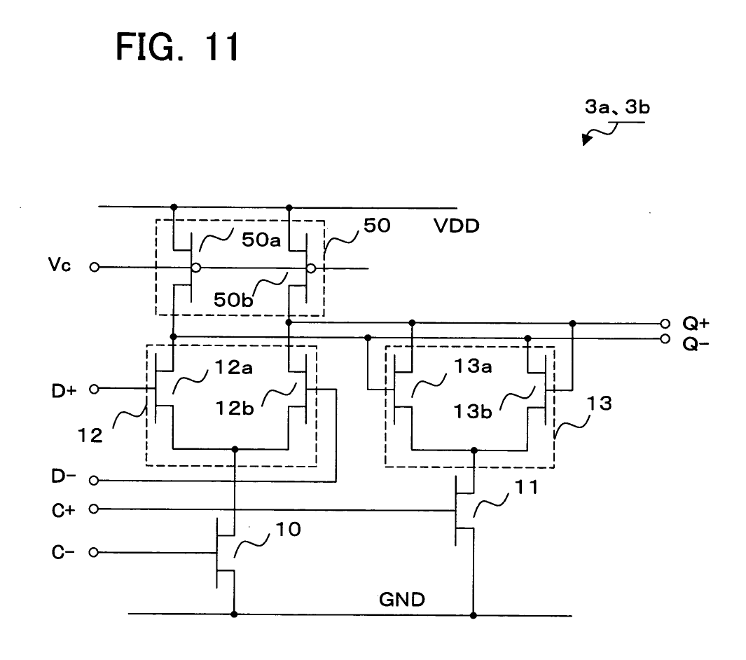

FIG. 11 is a circuit diagram illustrating the structure of the latch circuits 3a, 3b. Characters in FIG. 11 identical with those in FIG. 4 identical the same components. The latch circuit shown in FIG. 11 differs from the latch circuit of FIG. 4 in that the loads 14a, 14b of FIG. 4 are replaced by PMOS transistors 50a, 50b, respectively, and is identical with the latch circuit of FIG. 4 in other respects. The PMOS transistors 50a, 50b have their sources connected to the power supply VDD and have their gates tied common and connected to the control terminal Vc. The output terminals Q−, Q+are connected to the drains of the PMOS transistors 50a, 50b, respectively.

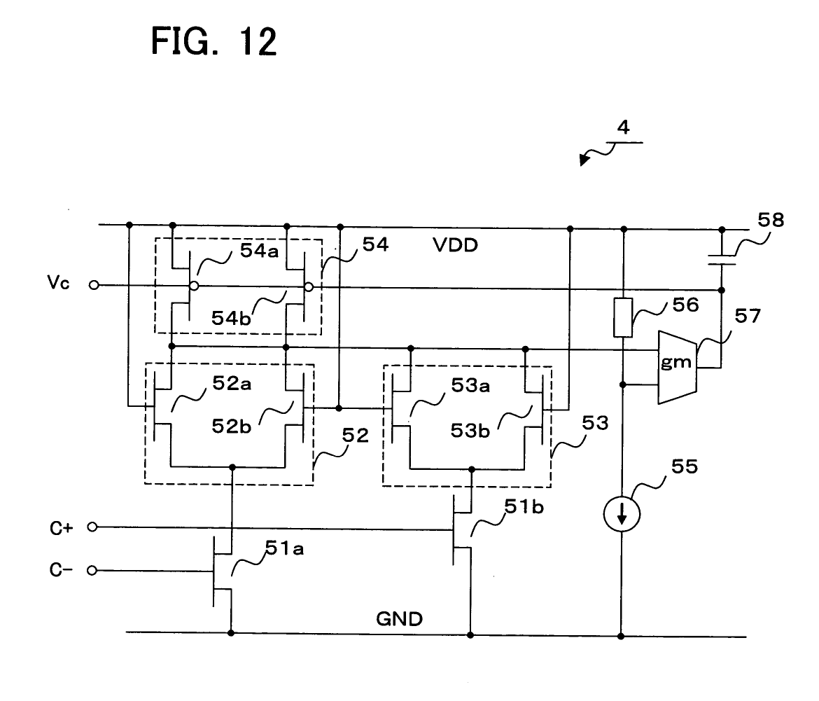

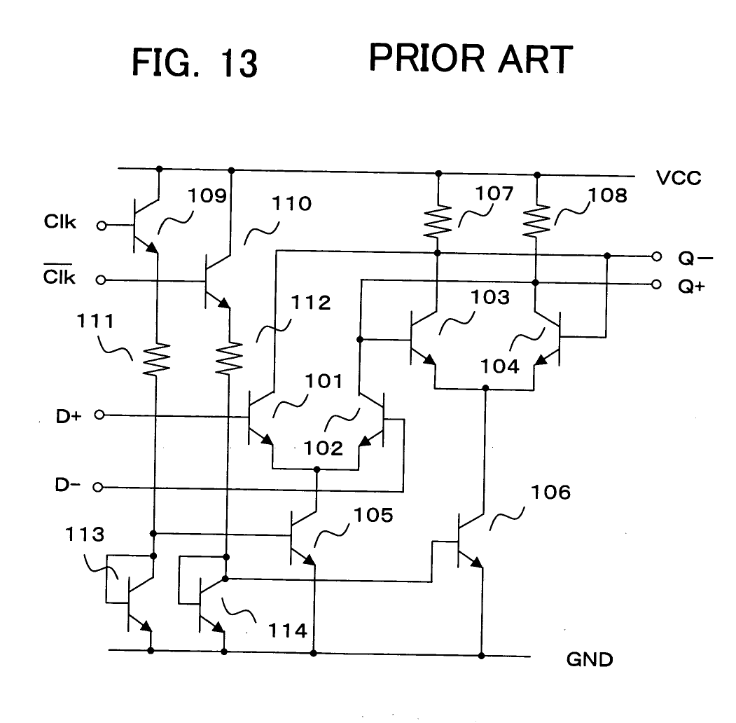

FIG. 12 is a circuit diagram illustrating the structure of the control circuit 4. The control circuit 4 shown in FIG. 12 has NMOS transistors 51a, 51b, 52a, 52b, 53a, 53b, PMOS transistors 54a, 54b, a current source 55, load 56, amplifier 57 and capacitor 58. The NMOS transistors 51a, 51b, 52a, 52b, 53a, 53b and PMOS transistors 54a, 54b are equivalent transistors that correspond to the NMOS transistors 10, 11, 12a, 12b, 13a, 13b and PMOS transistors 50a, 50b, respectively, shown in FIG. 11, and the control circuit 4 of FIG. 12 is a replica of the latch circuit shown in FIG. 11. However, in the circuit included in FIG. 12, the portions corresponding to the output terminals Q−, Q+ in the latch circuit of FIG. 11 are short-circuited. In order to detect the average amplitude of the signals output by the latch circuits 3a, 3b, the gates of the NMOS transistors 52a, 52b, 53a, 53b are connected to the power supply VDD to place the MOS transistors 52a, 52b, 53a, 53b in the conductive state.

The amplifier 57 has a first input terminal that is connected to the current source 55 and load 56 and receives a reference voltage generated in the load 56 by the current source 55, and a second input terminal that is connected to the drains of the NMOS transistors 52a, 52b, 53a, 53b and PMOS transistors 54a, 54b and receives the output voltage of the replica circuit that corresponds to the latch circuit of FIG. 11. The amplifier 57 compares the output voltage of the replica circuit with the reference voltage and delivers its output signal to the gates of the PMOS transistors 54a, 54b via a capacitor 58 that removes the high-frequency part of the signal.

The control circuit 4, which is constructed as set forth above, controls the gate voltage of the load PMOS transistors 54a, 54b in such a manner that the output voltage of the replica of the latch circuit will become equal to the reference voltage. By outputting this control voltage from terminal Vc and supplying it to the control terminals Vc of the latch circuits 3a, 3b, the output amplitude of the latch circuits 3a, 3b is rendered constant. As a result, the flip-flop circuit can be made to operate stably.

It is preferred that flip-flop circuits according to the second embodiment be mounted on the same chip, just as in the first embodiment. In particular, owing to the existence of the replica circuit on the same chip as that of the original (replicated) circuit, differences from one MOS transistor to another are reduced, the operating environment of the MOS transistors is rendered homogeneous and the flip-flop circuits operate more stably.

As many apparently widely different embodiments of the present invention can be made without departing from the spirit and scope thereof, it is to be understood that the invention is not limited to the specific embodiments thereof except as defined in the appended claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A flip-flop circuit comprising:
a clock buffer circuit that outputs a clock signal with an offset, the clock signal having a threshold-value voltage of a transistor as an offset voltage; and
a latch circuit so adapted that an input signal is output upon switching between a data-through operation and a data latching operation with respect to the input signal by operating the transistor, which has a threshold-value voltage, by the clock signal with the offset.

2. The circuit according to claim 1, wherein the clock signal with the offset comprises a set of differential clock signals with an offset, the differential signals being opposite in phase from each other; and
said latch circuit includes:
a first differential pair, in which the input signal is input as differential data, for performing a data-through operation to output the data to a pair of differential data output terminals;
a second differential pair for subjecting the differential data, which is output by said first differential pair, to a data holding operation and then outputting the data to the differential data output terminal;
a first transistor, which has a gate terminal that receives one clock signal of the differential clock signal with the offset, for driving said first differential pair when this one clock signal attains an active level; and
a second transistor, which has a gate terminal that receives the other clock signal of the differential clock signal with the offset, for driving said second differential pair when this other clock signal attains an active level;
the offset voltage being decided in such a manner that the sum of driving currents of said first and second transistors is rendered constant.

3. The circuit according to claim 2, wherein said second differential pair comprises third and fourth transistors;
said first transistor has a source terminal connected to ground and a drain terminal connected to a common-source side of said first differential pair, first and second loads and the differential data output terminals being connected to a drain side of said first differential pair;
said second terminal has as ource terminal connected to ground and a drain terminal connected to a common-source side of said second differential pair; and
said third and fourth transistors have gate and drain terminals, respectively, tied together and connected to one of the differential data output terminals, and said third and fourth transistors have drain and gate terminals, respectively, tied together and connected to the other of the differential data output terminals.

4. The circuit according to claim 1, wherein said clock buffer circuit comprises:
a third differential pair that receives differential clock signals as an input;
a current source for driving said third differential pair;
third and fourth loads having first ends connected to respective ones of outputs of said third differential pair;
a pair of clock signal output terminals, which are connected to respective ones of the outputs of said third differential pair, for outputting the clock signal with the offset as differential clock signals; and
an offset voltage generating circuit, to which other ends of said third and fourth loads are connected in common, for generating the offset voltage.

5. The circuit according to claim 4, wherein said offset voltage generating circuit comprises a fifth transistor having gate and drain terminals tied together and connected to said third and fourth loads, and a source terminal connected to ground.

6. The circuit according to claim 4, wherein said offset voltage generating circuit comprises:
a sixth transistor having gate and drain terminals tied together and connected to a current source, and a source terminal connected to ground; and
a voltage follower receiving drain potential of said sixth transistor as an input and having an output connected to said third and fourth loads.

7. A flip-flop circuit comprising:
a clock buffer circuit that outputs a clock signal with an offset, the clock signal having a threshold-value voltage of a transistor as an offset voltage; and
a latch circuit so adapted that an input signal is output upon switching between a data-through operation and a data latching operation with respect to the input signal by operating the transistor, which has a threshold-value voltage, by the clock signal with the offset,
wherein said clock buffer circuit comprises:
a third differential pair that receives differential clock signals as an input;
a current source for driving said third differential pair;
third and fourth loads having first ends connected to respective ones of outputs of said third differential pair;
a pair of clock signal output terminals, which are connected to respective ones of the outputs of said third differential pair, for outputting the clock signal with the offset as differential clock signals; and
an offset voltage generating circuit, to which other ends of said third and fourth loads are connected in common, for generating the offset voltage,
wherein said third and fourth loads of said clock buffer circuit comprise seventh and eighth transistors, and said clock buffer circuit comprises:
ninth and tenth transistors equivalent to said first and second transistors, respectively, in said flip-flop circuit set forth in claim 3;
loads, which are connected to drains of said ninth and tenth transistors, respectively, equivalent to the first and second loads in said flip-flop circuit set forth in claim 3;
a second amplifier, which has a first input terminal to which the drains of said ninth and tenth transistors are connected in common and a second input terminal to which a first reference voltage is supplied, for amplifying a difference voltage across these first and second input terminals; and
a second capacitor, which is connected to an output of said second amplifier, for converting output current of said second amplifier to voltage;
said ninth and tenth transistors having gates to which respective ones of the pair of clock signal input terminals are connected;
the output of said second amplifier being connected to gate terminals of said seventh and eighth transistors.

8. The circuit according to claim 1, further comprising a control circuit that generates a second reference voltage in order to perform control so as to render constant an output of said latch circuit, to output a control signal to said latch circuit based upon the second reference voltage;
wherein said latch circuit is controlled based upon the control signal.

9. A flip-flop circuit comprising:
a clock buffer circuit that outputs a clock signal with an offset, the clock signal having a threshold-value voltage of a transistor as an offset voltage; and
a latch circuit so adapted that an input signal is output upon switching between a data-through operation and a data latching operation with respect to the input signal by operating the transistor, which has a threshold-value voltage, by the clock signal with the offset, and
a control circuit that generates a second reference voltage in order to perform control so as to render constant an output of said latch circuit, to output a control signal to said latch circuit based upon the second reference voltage;
wherein said latch circuit is controlled based upon the control signal,
wherein said latch circuit is a circuit in which the first and second loads in the flip-flop circuit set forth in claim 3 comprise 11th and 12th transistors, respectively, and the control signal is supplied to both gate terminals so as to control resistance values of said 11th and 12th transistors; and
said control circuit further comprises:
a circuit in which all gate terminals of said first and second differential pairs in said latch circuit are connected to a power supply and all drain terminals are tied together to construct said latch circuit;
a third amplifier, which has a first input terminal to which all drain terminals are connected and a second input terminal to which the second reference voltage is supplied, for amplifying a difference voltage across these first and second terminals; and
a third capacitor, which is connected to an output of said third amplifier, for converting output current of said third amplifier to voltage;
the output of said third amplifier being connected to gate terminals of load transistors of said first and second differential pairs and being adopted as the control signal.

10. A semiconductor device in which flip-flop circuits set forth in claim 1 is provided on the same chip.
